(19) United States
(12) Patent Application Publication
(10) Pub. No.: US 2025/0287819 A1
(43) Pub. Date: Sep. 11, 2025

(54) DISPLAY PANEL AND DISPLAY APPARATUS

(71) Applicant: Wuhan Tianma Micro-Electronics Co., Ltd., Wuhan (CN)

(72) Inventor: Zilin OUYANG, Wuhan (CN)

(21) Appl. No.: 18/731,791

(22) Filed: Jun. 3, 2024

(30) Foreign Application Priority Data
Mar. 8, 2024 (CN) 202410267207.9

(51) Int. Cl. H10K 59/80; G06F 3/041; G06F 3/044; H10K 59/35; H10K 59/40

(52) U.S. Cl. CPC H10K 59/878; G06F 3/0412; G06F 3/0443; H10K 59/353; H10K 59/40; G06F 3/0446; G06F 2203/04111

(57) ABSTRACT

A display panel includes a substrate, a light-emitting unit, and a touch component. The light-emitting unit is arranged on a side of the substrate, and has multiple first light-emitting units emitting light of a same color. The touch component is arranged on a side of the light-emitting unit away from the substrate, and has a touch trace. The touch trace has a first segment and a second segment. The first segment and the second segment are distributed along a periphery of a same first light-emitting unit. The first segment and the second segment extend in different directions. The first segment is provided with a first slit that extends through the first segment in its thickness direction. Multiple first segments on peripheries of multiple first light-emitting units extend in a same direction.

### CROSS-REFERENCE TO RELATED APPLICATION

This application claims priority to Chinese Patent Application No. 202410267207.9, filed on Mar. 8, 2024, the entire content of which is incorporated herein by reference.

### TECHNICAL FIELD

The present disclosure relates to the technical field of display device and, in particular, to a display panel, a display apparatus, and a control method.

### BACKGROUND

With the continuous development of technology, there is an increasing demand for display devices. In order to achieve a full-screen touch function, a touch metal layer is arranged over a light-emitting layer of a display device. Since the touch metal layer has an uneven shape and is located on one side of the light-emitting layer facing a light-exiting surface of the display device, it will affect the display effect of the display device.

### SUMMARY

One aspect of the present disclosure provides a display panel. The display panel includes a substrate, a light-emitting unit, and a touch component. The light-emitting unit is arranged on a side of the substrate, and has multiple first light-emitting units emitting light of a same color. The touch component is arranged on a side of the light-emitting unit away from the substrate, and has a touch trace. The touch trace has a first segment and a second segment. The first segment and the second segment are distributed along a periphery of a same first light-emitting unit. The first segment and the second segment extend in different directions. The first segment is provided with a first slit that extends through the first segment in its thickness direction. Multiple first segments on peripheries of multiple first light-emitting units extend in a same direction.

Another aspect of the present disclosure provides a display apparatus. The display apparatus includes a display panel. The display panel includes a substrate, a light-emitting unit, and a touch component. The light-emitting unit is arranged on a side of the substrate, and has multiple first light-emitting units emitting light of a same color. The touch component is arranged on a side of the light-emitting unit away from the substrate, and has a touch trace. The touch trace has a first segment and a second segment. The first segment and the second segment are distributed along a periphery of a same first light-emitting unit. The first segment and the second segment extend in different directions. The first segment is provided with a first slit that extends through the first segment in its thickness direction. Multiple first segments on peripheries of multiple first light-emitting units extend in a same direction.

### BRIEF DESCRIPTION OF THE DRAWINGS

Upon reading the detailed description of the non-limiting embodiments provided below with reference to the accompanying drawings, other features, objects and advantages of the present disclosure will become more apparent and be encompassed with the scope of the present disclosure. Identical or similar reference numerals in the drawings may be used to denote identical or similar features.

FIG. 1 illustrates a schematic structural diagram of a display panel according to one embodiment of the present disclosure.

FIG. 2 illustrates a schematic diagram of a locally enlarged structure of FIG. 1 according to one embodiment of the present disclosure.

FIG. 3 illustrates a schematic diagram of a locally enlarged structure at P in FIG. 2.

FIG. 4 illustrates a cross-sectional view at A-A in FIG. 3.

FIG. 5 illustrates a schematic diagram of a locally enlarged structure of FIG. 3 according to one embodiment of the present disclosure.

FIG. 6 illustrates a schematic diagram of a locally enlarged structure of FIG. 3 according to another embodiment of the present disclosure.

FIG. 7 illustrates a schematic diagram of a locally enlarged structure at P in FIG. 2 according to another embodiment of the present disclosure.

FIG. 8 illustrates a schematic diagram of a locally enlarged structure of FIG. 7.

FIG. 9 illustrates a schematic diagram of a locally enlarged structure of FIG. 3 according to another embodiment of the present disclosure.

FIG. 10 illustrates a schematic diagram of a locally enlarged structure at Q in FIG. 2.

FIG. 11 illustrates a schematic diagram of a locally enlarged structure of FIG. 3 according to another embodiment of the present disclosure.

FIG. 12 illustrates a schematic diagram of a locally enlarged structure of FIG. 1 according to another embodiment of the present disclosure.

FIG. 13 illustrates a cross-sectional view at B-B in FIG. 12.

FIG. 14 illustrates a cross-sectional view at A-A in FIG. 3 according to another embodiment of the present disclosure.

FIG. 15 illustrates a schematic structural diagram of a display apparatus provided by the present disclosure.

### DETAILED DESCRIPTION OF THE EMBODIMENTS

Features and exemplary embodiments of various aspects of the present disclosure are described in detail below. In the following detailed description, numerous specific details are outlined to provide a thorough understanding of the application. However, it will be apparent to those persons of ordinary skill in the art, that the present disclosure can be implemented without some of these specific details. The following description of embodiments is merely intended to provide a better understanding of the present disclosure by illustrating examples thereof. In the drawings and the following description, at least some well-known structures and techniques are not shown to avoid unnecessarily obscuring the present disclosure. The dimensions of some structures may be exaggerated for clarity. Furthermore, the features, structures, or characteristics described below may be combined in any suitable manner in one or more embodiments.

In the description of the present disclosure, it should be noted that, unless otherwise indicated, the terms such as “multiple” and “a plurality” mean two or more. Terms such as “upper”, “lower”, “left”, “right”, “inside”, “outside”, etc., indicating positional relationships or directions are for convenience in describing the present disclosure and simplifying the description, rather than indicating or implying that the device or component referred to have specific orientations, be constructed, or operated in specific directions, and thus cannot be understood as limiting the present application. Additionally, terms such as “first”, “second”, etc., are used solely for descriptive purposes and cannot be construed as indicating or implying relative importance.

The directional terms appearing in the following description are in accordance with the directions indicated in the figures and do not specifically limit the structure of embodiments of the present disclosure. Additionally, it should be noted in the description of the present disclosure that, unless otherwise explicitly specified and limited, terms such as “installation” and “connection” should be broadly construed. For example, they could mean a fixed connection, a detachable connection, or an integral connection. They can be directly connected or indirectly connected. The specific meanings of the above terms in the present disclosure can be understood by those persons of ordinary skill in the art, depending on the specific circumstances.

A display panel includes a light-emitting unit and a touch trace located on the light-emitting unit. The touch trace includes an effective electrode and a dummy electrode. To avoid short-circuiting between the effective electrode and the dummy electrode, a slit is set between the effective electrode and the dummy electrode, causing them to be spaced apart and insulated from each other. When the display panel displays a monochrome image, diagonal display defects may occur. Further investigation reveals that due to the arrangement of the touch trace around the light-emitting unit, the shapes of the effective electrode and the dummy electrode may differ at different positions. This causes slits on the peripheries of light-emitting units of a same color to extend in different directions, leading to different light reflections at different positions under a large viewing angle. This results in a diagonal pattern in the monochrome image display.

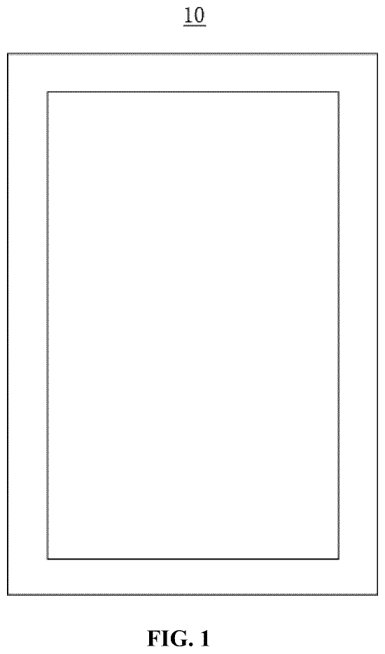

To better convey the present disclosure, detailed descriptions of embodiments of the display panel and the display apparatus of the present disclosure are provided below with reference to FIGS. 1 to 15.

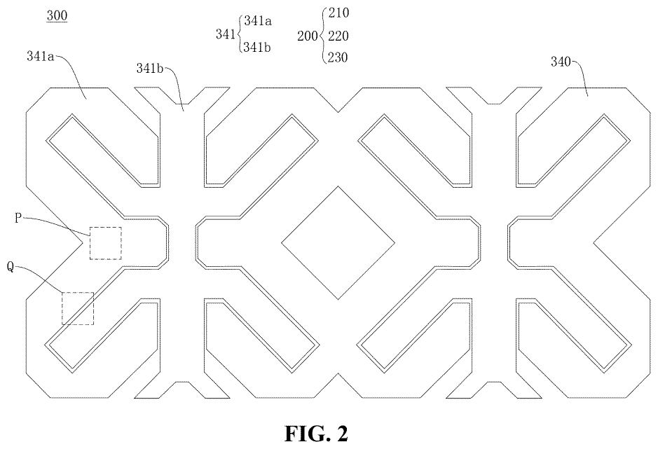

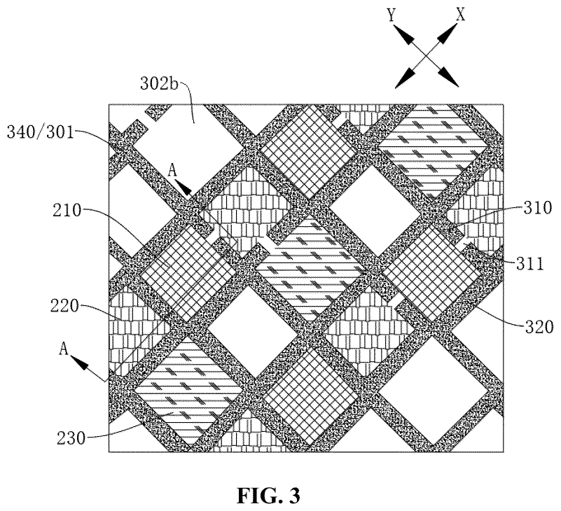

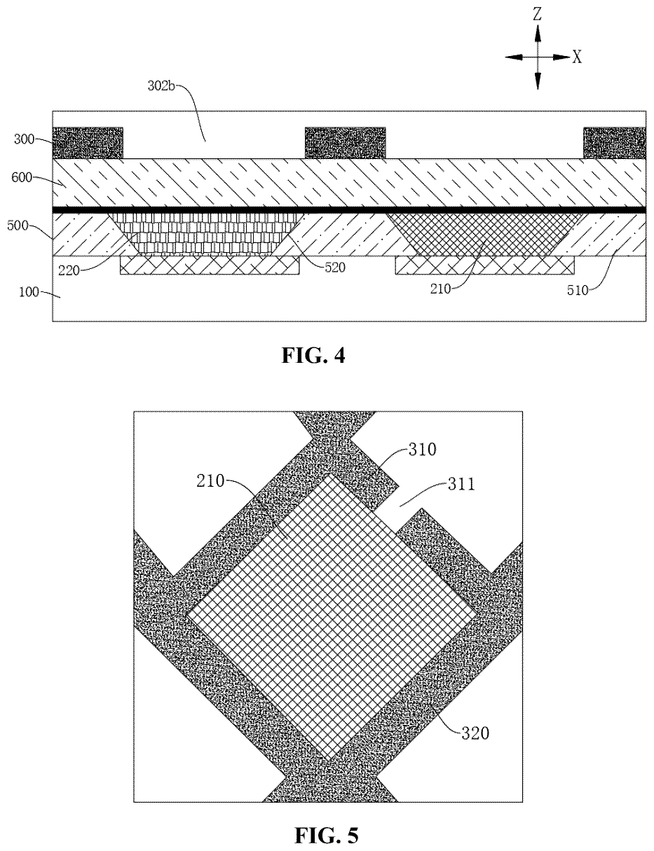

FIG. 1 illustrates a schematic diagram of a local structure of a display panel 10 provided by the present disclosure. FIG. 2 illustrates an enlarged schematic diagram of the local structure of FIG. 1. FIG. 3 is an enlarged schematic diagram of position P in FIG. 2. FIG. 4 is a partial cross-sectional view of FIG. 3.

As shown in FIGS. 1 to 4, the display panel 10 provided by embodiments of the present disclosure includes a substrate 100, a light-emitting unit 200, and a touch component 300. The light-emitting unit 200 is arranged on a side of the substrate 100 and includes a plurality of first light-emitting units 210 that emit light of a same color. The touch component 300 is arranged on a side of the light-emitting unit 200 away from the substrate 100 and includes a touch trace 301. The touch trace 301 includes a first segment 310 and a second segment 320 distributed around a same first light-emitting unit 210. The first segment 310 and the second segment 320 extend in different directions. The first segment 310 is provided with a first slit 311 that extends through the first segment 310 along a width direction of the first segment 310. A plurality of first segments 310 on peripheries of the plurality of first light-emitting units 210 extends in a same direction.

In the display panel 10 provided in embodiments of the present disclosure, the display panel 10 includes a substrate 100, a light-emitting unit 200, and a touch component 300. The light-emitting unit 200 is located on a side of the substrate 100 to achieve the light-emitting display function of the display panel 10. The touch component 300 is arranged on the side of the light-emitting unit 200 away from the substrate 100 to achieve the touch function of the display panel 10. The touch component 300 includes a touch trace 301. Light emitted from the first light-emitting unit 210 will exit through the touch trace 301. Therefore, the touch trace 301 will affect the display effect of the first light-emitting unit 210. The touch trace 301 includes the first segment 310 and the second segment 320 with different extension directions. The first segment 310 and the second segment 320 are distributed around a periphery of a first large light-emitting circle. A first slit 311 is provided on the first segment 310. The first slit 311 will affect the large-angle light-emitting effect of the first light-emitting unit 210. In embodiments of the present disclosure, an extension direction of a plurality of first segments 310 around a periphery of the plurality of first light-emitting units 210 is the same, i.e., an extension direction of a plurality of first slits 311 is the same, thereby making the light emission effects of the plurality of first light-emitting units 210 of a same color tend to be consistent, improving the display effect of the display panel 10.

There are various ways to set the substrate 100. The substrate 100 can include a supporting base and an array substrate set on the supporting base. The array substrate can include a pixel driving circuit.

There are various ways to set the supporting base, such as the supporting base can be a rigid supporting base, and a material of the supporting base includes a rigid material such as glass. Alternatively, the supporting base can be a flexible supporting base, and a material of the supporting base includes a flexible material such as polyimide.

The array substrate may include a first conductive layer, a second conductive layer, and a third conductive layer that are set and stacked in sequence on a side of the supporting base. An insulating layer is provided between adjacent conductive layers. For example, the pixel driving circuit includes a transistor and a storage capacitor. The transistor includes a semiconductor, a gate electrode, a source electrode, and a drain electrode. The storage capacitor includes a first electrode plate and a second electrode plate. As an example, the gate electrode and the first electrode plate can be located on the first conductive layer. The second electrode plate can be located on the second conductive layer. The source electrode and the drain electrode can be located on the third conductive layer.

Optionally, the display panel 10 can be an organic light-emitting diode display panel. A pixel defining layer 500 is set on the substrate 100. The pixel defining layer 500 includes a pixel defining part and a pixel opening 520 in the pixel defining part. The light-emitting unit 200 is located in the pixel opening 520. Alternatively, the display panel 10 can also be a micro-light emitting diode display panel. A soldering pad is set on the substrate 100. The light-emitting unit 200 includes a contact electrode. The light-emitting unit 200 is set on the substrate 100. The contact electrode of the light-emitting unit 200 is electrically connected to the soldering pad. Alternatively, the display panel 10 can also be a liquid crystal display panel, where the light-emitting unit 200 includes a light source, a liquid crystal layer set on the light source, and a light filtering unit.

Optionally, an encapsulation layer 600 is provided on the side of the light-emitting unit 200 away from the substrate 100. The encapsulation layer 600 is used to provide sealing protection to the light-emitting unit 200. Optionally, the touch component 300 is disposed on a side of the encapsulation layer 600 away from the light-emitting unit 200 to improve the encapsulation effect of the touch component 300 on the encapsulation layer 600.

Optionally, the light-emitting unit 200 can further include a second light-emitting unit 220 and a third light-emitting unit 230. The light-emitting colors of the first light-emitting unit 210, the second light-emitting unit 220, and the third light-emitting unit 230 are different to achieve the color display of the display panel 10. One of the first light-emitting unit 210, the second light-emitting unit 220, and the third light-emitting unit 230 is used to emit red light, another is used to emit green light, and the last one is used to emit blue light.

The touch trace 301 includes a first segment 310 and a second segment 320 distributed on the periphery of the same first light-emitting unit 210. This means orthographic projections of the first segment 310 and the second segment 320 on the substrate 100 are located on the periphery of an orthographic projection of the first light-emitting unit 210 on the substrate 100.

For example, the first segment 310 has a length direction and a width direction. An extension dimension of the first segment 310 in the length direction is greater than an extension dimension of the first segment 310 in the width direction. The first slit 311 traverses the first segment 310 in the width direction. Optionally, the first segment 310 can correspond to a portion of the touch trace 301 that is located on the periphery of the first light-emitting unit 210 and extending in a same direction. For example, the first segment 310 can correspond to a portion of the touch trace 301 that is located at the periphery of the first light-emitting unit 210 and extending in a same direction. Optionally, the second segment 320 can correspond to a portion of the touch trace 301 that is located at the periphery of the first light-emitting unit 210 and extending in a same direction. The extension directions of the second segment 320 and the first segment 310 are different.

As shown in FIG. 5, a first segment 310 may be provided on the periphery of a same first light-emitting unit 210. The first segment 310 is located on one side of the first light-emitting unit 210.

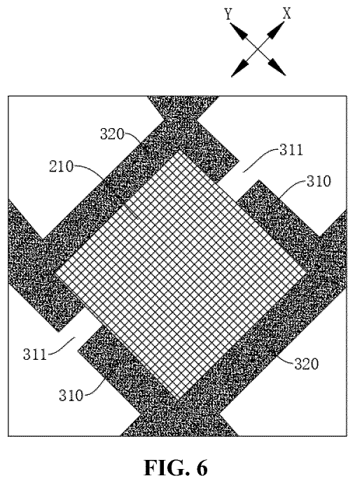

In some optional embodiments, as shown in FIG. 6, two or more first segments 310 with a same extension direction are provided on the periphery of the same first light-emitting unit 210. In some optional embodiments, first slits 311 are provided on more than two touch traces 301 with a same extension direction on the periphery of the same first light-emitting unit 210 to form more than two first segments 310. This causes the light-emitting effect on the periphery of the same first light-emitting unit 210 to be more consistent.

Optionally, the touch trace 301 includes two first segments 310 oppositely arranged along the first direction X and two second segments 320 oppositely arranged along the second direction Y. Two first segments 310 and two second segments 320 are connected alternately end to end around the first light-emitting unit 210, and the first direction X and the second direction Y intersect. This addresses the blocking of the touch trace 301 of the light-emitting unit 200 on the light-emitting effect of the display panel 10. For example, two first segments 310 and two second segments 320 are alternately connected to form a hollow space. An orthographic projection of the first light-emitting unit 210 on the substrate 100 is located within an orthographic projection of the hollow space on the substrate 100 to improve the influence of the first segment 310 and the second segment 320 on the light-emitting effect of the first light-emitting unit 210.

Optionally, the first direction X and the second direction Y are perpendicular. Optionally, the first direction X can be the width direction of the first segment 310, and the second direction Y can be the length direction of the first segment 310. Therefore, the first slit 311 can be set to traverse the first segment 310 along the first direction X. Optionally, the first direction X can be a length direction of the second segment 320, and the second direction Y can be a width direction of the second segment 320.

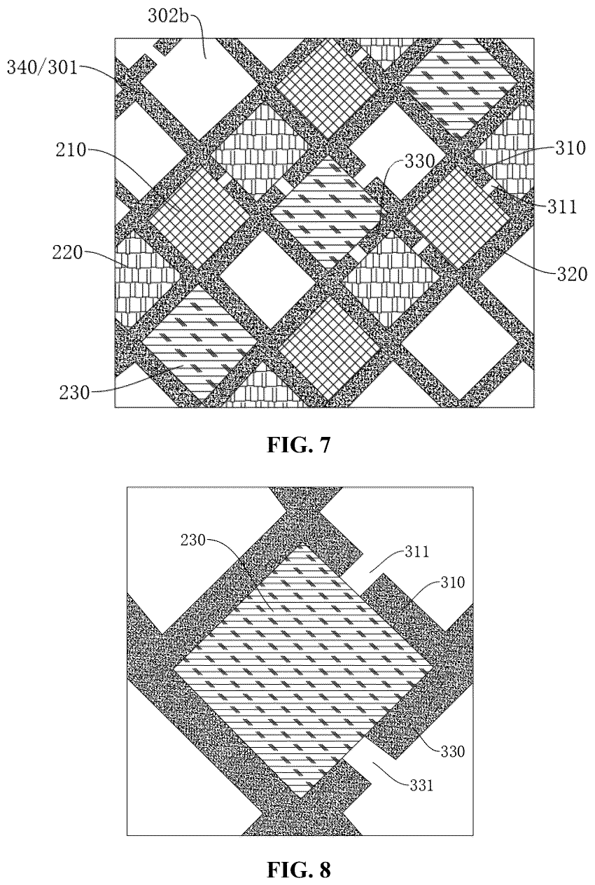

In some optional embodiments, as shown in FIG. 7, the light-emitting unit 200 further includes a plurality of second light-emitting units 220 with a same light-emitting color and a plurality of third light-emitting units 230 with a same light-emitting color. A first segment 310 is distributed on the periphery of the second light-emitting unit 220 and/or the third light-emitting unit 230. That is to say, peripheries of the second light-emitting unit 220 and/or the third light-emitting unit 230 are also provided with first slits 311 extending in a same direction to ensure consistency in the light emission effects of the plurality of second light-emitting units 220 and/or the plurality of third light-emitting units 230. This improves the light emission effect of the display panel 10.

Alternatively, in other embodiments, as shown in FIG. 8, the touch trace 301 includes a third segment 330 distributed around a same second light-emitting unit 220 and/or a third light-emitting unit 230. An extension direction of the third segment 330 is different from that of the first segments 310. A second slit 331 is provided traversing along the width direction on the third segment 330. In these optional embodiments, peripheries of the second light-emitting unit 220 and/or the third light-emitting unit 230 can correspondingly be provided with a second slit 331 that extends in a direction different than the first slit 311. This ensures the pattern of the touch trace 301 to meet functional requirements.

Optionally, the extension direction of the third segment 330 can be the same as that of the second segment 320. The difference between the third segment 330 and the second segment 320 is that the third segment 330 is provided with a second slit 331, while the second segment 320 is not necessarily provided with a slit. That is, first slits 311 extending in a same direction are provided on first segments 310 that are on peripheries of the plurality of first light-emitting units 210. Second segments 320 that are on the peripheries of the plurality of first light-emitting units 210 are not provided with slits. Directions of the slits on peripheries of the plurality of first light-emitting units 210 are consistent, thereby making the light-emitting effects of the plurality of first light-emitting units 210 more consistent.

In some optional embodiments, the first light-emitting unit 210 is a red light-emitting unit 200. First slits 311 are provided on first segments 310 that are on peripheries of the plurality of red light-emitting units 200. That is to say, the first slits 311 extending in a same direction are provided on the first segments 310 that are on peripheries of the plurality of red light-emitting units 200. Directions of the slits on the peripheries of the plurality of red light-emitting units 200 are consistent, thereby making the light emission effects of the plurality of red light-emitting units 200 more consistent.

Among a plurality of light-emitting units 200 with different emitting colors, the inconsistent light-emitting effect of the red light-emitting unit 200 is more perceptible to the human eye. The light-emitting effect of the red light-emitting unit 200 is more likely to affect the overall light-emitting effect of the display panel 10. In one exemplary embodiment, by ensuring consistency in the direction of slits on the peripheries of the plurality of red light-emitting units 200, the light-emitting effects of the plurality of red light-emitting units 200 are more consistent, which can better improve the display effect of the display panel 10.

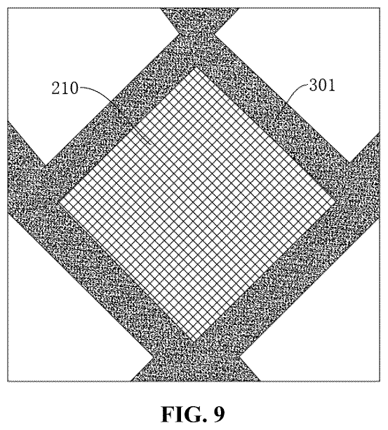

In some other optional embodiments, as shown in FIG. 9, the light-emitting unit 200 further includes a red light-emitting unit 200 that emits light in a different color from the first light-emitting unit 210. The touch trace 301 includes a ring segment located on the periphery of the red light-emitting unit 200 that is in a closed ring shape.

In these optional embodiments, the light-emitting color of the first light-emitting unit 210 is not red. The light-emitting unit 200 further includes a red light-emitting unit 200. The touch trace 301 located around the red light-emitting unit 200 forms a closed ring shape, that is, there are no slits on the touch trace 301 around the red light-emitting unit 200, making the light-emitting effects of the red light-emitting unit 200 at different positions more consistent. This can further improve the display effect of the display panel 10.

In one exemplary embodiment, as shown in FIGS. 2 to 5, if there are slits around the red light-emitting unit 200, the slits around the red light-emitting unit 200 are all first slits 311. The slits on the peripheries of the red light-emitting unit 200 extend in a same direction; Alternatively, as shown in FIG. 9, no slits are provided on the periphery of the red light-emitting unit 200, thereby making the light-emitting effects of red light-emitting units 200 at different positions more consistent and improving the display effect of the display panel 10.

In some optional embodiments, quantities of first slits 311 on a same side of the periphery of two or more first light-emitting units 210 is equal. This makes the light-emitting effects on peripheries of different first light-emitting units 210 more consistent, which can better improve the display effect of the display panel 10.

Optionally, the quantities of first slits 311 on the same side of two or more first light-emitting units 210 are equal, making the light-emitting effects on the periphery of different first light-emitting units 210 more consistent.

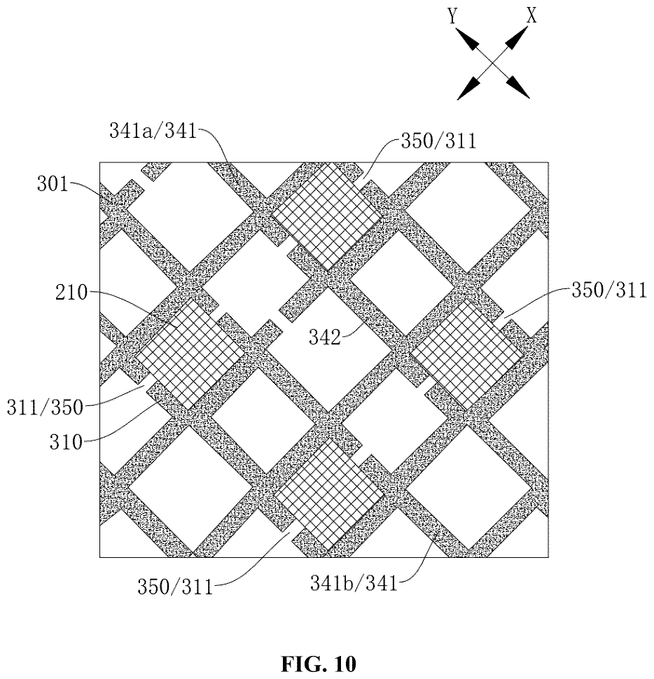

Optionally, as shown in FIGS. 2 and 10, the touch component 300 includes a plurality of touch electrodes 340. A touch electrode 340 includes a touch trace 301. The touch electrode 340 can be a self-capacitive touch electrode or a mutual-capacitive touch electrode. Optionally, the touch trace 301 forms a grid pattern, and by setting separation slits 350 at different positions along the touch trace 301, the touch trace 301 is divided into a plurality of touch electrodes 340.

In some optional embodiments, as further illustrated in FIGS. 2 and 10, the touch trace 301 includes a plurality of touch electrodes 340. At least two adjacent touch electrodes 340 are spaced apart to form a separation slit 350. At least one first slit 311 is reused as the separation slit 350.

In these optional embodiments, a separation slit 350 needs to be set on the touch trace 301 to insulate a plurality of touch electrodes 340 from each other. At least one first slit 311 is reused as the separation slit 350, i.e., the first slit 311 can be used to divide the touch trace 301 into a plurality of touch electrodes 340. Reusing the first slit 311 and the separation slit 350 can reduce the total quantity of slits on the touch trace 301, improving the display effect of the display panel 10.

In some optional embodiments, as further illustrated in FIG. 10, the touch electrode 340 includes an effective electrode 341 and a dummy electrode 342. The effective electrode 341 is used to realize a touch function of the display panel 10. The dummy electrode 342 can be used to fill vacancies between effective electrodes 341 or inside an effective electrode 341 to improve the display effect of the display panel 10 in the screen-off state.

In some optional embodiments, the separation slit 350 can be used to separate two effective electrodes 341, or the separation slit 350 can be used to separate the effective electrode 341 from the dummy electrode 342. For example, in some embodiments, the dummy electrode 342 includes at least one first segment 310, where a separation slit 311 can be set on the dummy electrode 342 to improve the effect of the first slit 311 on the touch function of the effective electrode 341.

In some optional embodiments, the effective electrode 341 includes a touch sensing electrode 341a and/or a touch driving electrode 341b. This allows the effective electrode 341 to realize the touch function through the touch sensing electrode 341a and/or the touch driving electrode 341b. Optionally, the touch electrode 340 is a mutual-capacitive touch electrode 340. The effective electrode 341 can include a touch sensing electrode 341a and a touch driving electrode 341b. In other embodiments, the touch electrode 340 can also be a self-capacitive touch electrode 340. The effective electrode 341 is a touch electrode 340 block arranged separately and connected to a touch processor.

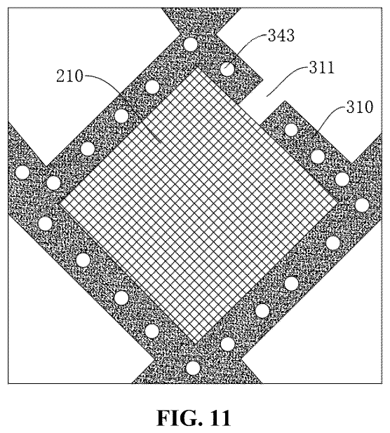

In some optional embodiments, as shown in FIG. 11, at least one touch electrode 340 includes a through-hole 343 that traverses the touch electrode 340. By setting the through-hole 343 on the touch electrode 340, a distribution area of the touch electrode 340 can be reduced, thereby addressing the parasitic capacitance between the touch electrode 340 and a conductive layer over the substrate 100, and enhancing the touch sensitivity.

Optionally, a plurality of through-holes 343 are spaced apart and distributed on the touch electrode 340. This further reduces the distribution area of the touch electrode 340, better addressing the issue of parasitic capacitance and improving touch sensitivity.

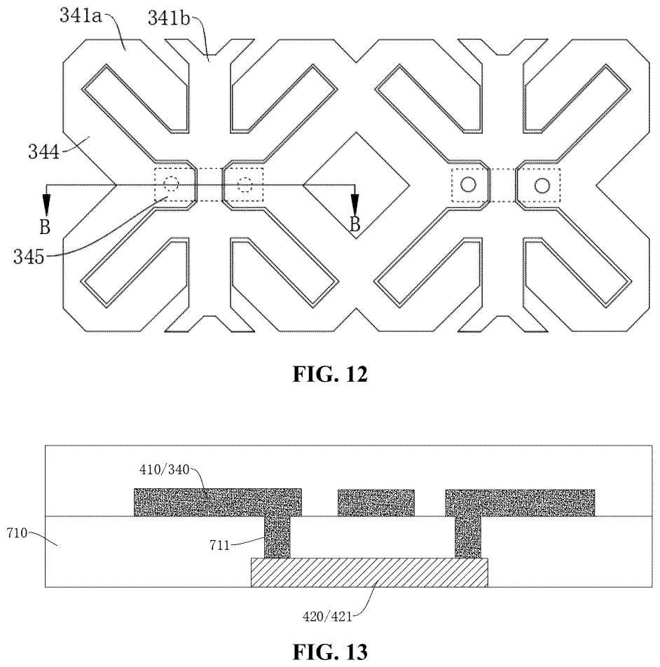

In some optional embodiments, as shown in FIGS. 12 and 13, the display panel 10 includes a first touch layer 410 and a second touch layer 420. A plurality of touch electrodes 340 is provided in the first touch layer 410. The second touch layer 420 is provided with a bridging part 421. At least two adjacent and spaced apart touch electrodes 340 are connected to each other through the bridging part 421. For example, two adjacent touch sensing electrodes 341a can be connected to each other through the bridging part 421. Alternatively, two adjacent touch driving electrodes 341b can be connected to each other through the bridging part 421. Optionally, a first insulating layer 710 is provided between the first touch layer 410 and the second touch layer 420. A via hole 711 is provided in the first insulating layer 710. The touch electrode 340 can connect a via hole 711 of the bridging part 421 by the via hole 711 of the touch electrode 340. The positions of the via hole 711 and the bridging part 421 are illustrated with dotted lines in FIG. 12.

Optionally, the touch electrode 340 includes a touch area 344 and a bridging area 345. An orthographic projection of the bridging area 345 on the substrate 100 overlaps with an orthographic projection of the bridging part 421 on the substrate 100. An orthographic projection of the touch area 344 on the substrate 100 is located outside the orthographic projection of the bridging part 421 on the substrate 100. The first segment 310 is located in the touch area 344.

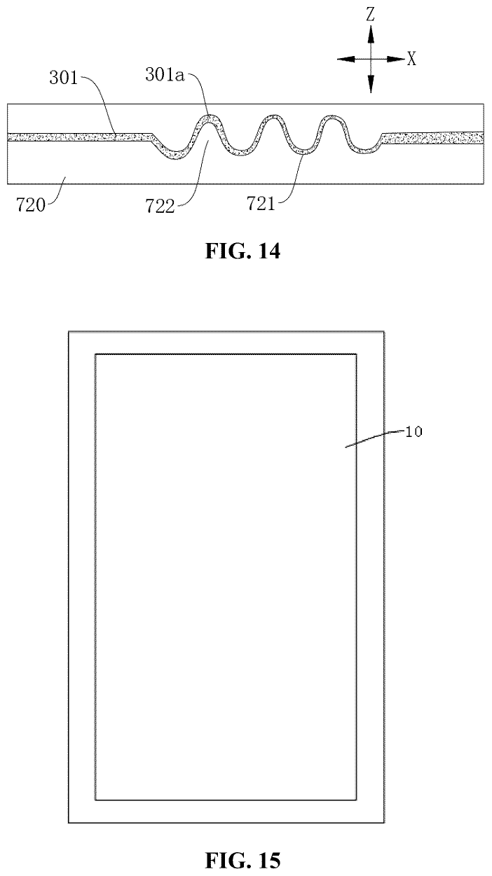

The touch trace 301, on the touch electrode 340 and overlapping with the bridging part 421, is usually specially designed. That is, the touch trace 301 inside the bridging area 345 is usually specially arranged, and the bridging area 345 occupies a relatively small proportion of the total area of the touch electrode 340. Therefore, the first segment 310 is disposed in the touch area 344. This is attributed to a larger area of the touch area 344, ensuring the display effect by arranging the first segment 310 in the touch area 344. Avoiding placing the first segment 310 in the bridging area 345 can simplify the structure of the touch trace 301. In some optional embodiments, as shown in FIG. 14, at least a portion of the surface of the touch trace 301 away from the light-emitting unit 200 is provided with a protrusion structure 301a.

In these optional embodiments, by setting the protrusion structure 301a on the surface of the touch trace 301, light can undergo diffuse reflection on the outer surface of the touch trace 301. This improves the display effect of the display panel 10 by reducing the reflection of ambient light on the touch trace 301.

Optionally, plasma etching or similar treatments can be applied to the touch trace 301 to form a pit structure and a protrusion structure 301a on the surface of the touch trace 301 away from the light-emitting unit 200. Alternatively, a second insulating layer 720 can be set on one side of the touch trace 301 facing the substrate 100. One surface of the second insulating layer 720 away from the substrate 100 can be patterned to form a groove 721 and a convex part 722. Then, a conductive material is deposited on one surface of the insulating layer with the groove 721 to form the touch trace 301. The conductive material deposited in the groove 721 forms the pit structure on one surface of the touch trace 301, while the conductive material deposited on the convex part 722 outside the groove 721 forms the protrusion structure 301a on one surface of the touch trace 301.

Optional, when the first touch layer 410 is located on one side of the second touch layer 420 away from the substrate 100, the second insulating layer 720 and the first insulating layer 710 that is located between the first touch layer 410 and the second touch layer 420 can be reused with each other. In other embodiments, when the first touch layer 410 is located on one side of the second touch layer 420 facing the substrate 100, the second insulating layer 720 can also serve as another insulating layer. The second insulating layer 720 and the first insulating layer 710 are different insulating layers.

Optionally, an entire touch trace 301 can be bent and protruded along a thickness direction Z to form the protrusion structure 301a. Alternatively, the protrusion structure 301a can be formed on the surface of the touch trace 301 away from the substrate 100, while the surface of the touch trace 301 facing the substrate 100 is flat. As long as the surface of the touch trace 301 away from the substrate 100 has the protrusion structure 301a, the protrusion structure 301a is capable of reflecting light.

In some optional embodiments, the light-emitting unit 200 includes a red light-emitting unit 200, and at least a portion of one surface of the touch trace 301 located on the periphery of the red light-emitting unit 200 has the protrusion structure 301a.

In these optional embodiments, the protrusion structure 301a is arranged on at least a portion of the touch trace 301 on the periphery of the red light-emitting unit 200. Thus, light can undergo diffuse reflection on the periphery of the red light-emitting unit 200 to address the issue of reflected light on the periphery of the red light-emitting unit 200. This makes the light-emitting effect of the plurality of the red light-emitting units 200 more consistent, thereby improving the display effect of the display panel 10.

There are various locations for arranging the protrusion structure 301a. The protrusion structure 301a can be located on at least one of the first segment 310, the second segment 320, and the third segment 330.

In some optional embodiments, the protrusion structure 301a is set on the first segment 310, and the protrusion structure 301a is located on both sides of the first slit 311 in an extension direction of the first segment 310.

In these optional embodiments, due to the presence of the first slit 311 on the first segment 310, the location of the first slit 311 will not produce light reflection, while light reflection will occur on the first segment 310 that is located on both sides of the first slit 311. This results in significant differences in display between the first slit 311 and first segments 310 which are located on both sides of the first slit 311. By setting protrusion structures 301a on both sides of the first slit 311 in the extension direction of the first segment 310, the display difference between the first slit 311 and its periphery can be addressed, thereby better improving the display effect of the display panel 10.

Optionally, the protrusion structures 301a on both sides of the first slit 311 in the extension direction of the first segment 310 are symmetrically arranged with respect to the first slit 311. Thus, this makes the display effect on both sides of the first slit 311 more uniform, thereby better improving the display effect of the display panel 10.

Optionally, quantities of the protrusion structures 301a on both sides of the first slit 311 in the extending direction of the first segment 310 are consistent. This makes the display effect on both sides of the first slit 311 more uniform, thereby better improving the display effect of the display panel 10.

Optionally, as described above, when an extension length of the first segment 310 in the first direction X is greater than its extension length in the second direction Y, the extension direction of the first segment 310 is the first direction X. The first slit 311 can extend along the second direction Y. When the extension length of the first segment 310 in the second direction Y is greater than its extension length in the first direction X, the extension direction of the first segment 310 is the second direction Y. The first slit 311 can extend along the first direction X.

In some optional embodiments, multiple protrusion structures 301a are spaced apart along the extension direction of the touch trace 301. For example, the touch trace 301 can be in a wavy structure, or one surface of the touch trace 301 away from the substrate 100 has a wavy structure to form the multiple protrusion structures 301a spaced apart along their extension direction.

In these optional embodiments, by setting multiple protrusion structures 301a and having the multiple protrusion structures 301a spaced apart along the extension direction of the touch trace 301, the touch trace 301 can diffusely reflect light at different positions. This improves the display effect of the display panel 10.

In some optional embodiments, the touch trace 301 encloses a hollow area 302b. The orthographic projection of the light-emitting unit 200 on the substrate 100 is located in an orthographic projection of the hollow area 302b on the substrate 100. The first segment 310 is a portion of the touch trace 301 that surrounds the hollow area 302b. For example, two first segments 310, and two second segments 320 can be alternately distributed and connected to each other to form the hollow area 302b. Alternatively, two segments 310 and two third segments 330 can be alternately distributed and connected to each other to form the hollow area 302b.

In these optional embodiments, the touch trace 301 encloses the hollow area 302b. Light emitted by the light-emitting unit 200 can exit through the hollow area 302b to improve the light output of the touch trace 301 on the light-emitting unit 200.

In some optional embodiments, one first slit 311 is set on a same first segment 310, or a plurality of first slits 311 are set on a same first segment 310. The plurality of first slits 311 is spaced apart along the extension direction of the first segment 310.

In embodiments of the present disclosure, one first slit 311 can be set on the first segment 310, or a plurality of first slits 311 can be set on the first segment 310, to enrich the arrangement of the first slits 311. By reasonably setting the quantity and the position of the first slits 311, the purpose of separating the touch trace 301 into a plurality of mutually insulated touch electrodes 340 can be achieved, and the display effect of the display panel 10 can also be improved.

As shown in FIG. 15, embodiments of the present disclosure further provide a display apparatus. The apparatus includes the display panel 10 according to any one of the embodiments described above. The display apparatus has the beneficial effects of any one of the embodiments described above, which are not repeated here.

The display apparatus in embodiments of the present disclosure includes but is not limited to apparatuses with display functions such as mobile phones, personal digital assistant (PDA), tablets, e-books, televisions, access control systems, smart landlines, and consoles.

Although the present disclosure has been described with reference to preferred embodiments, various modifications may be made and equivalents may be substituted for components thereof without departing from the scope of the present disclosure. In particular, as long as there is no fundamental conflict, the technical features mentioned in various embodiments can be combined in any way. The present disclosure is not limited to specific embodiments disclosed herein but includes all technical solutions falling within the scope of the claims.

What is claimed is:

1. A display panel, comprising
a substrate;
a light-emitting unit, arranged on a side of the substrate, wherein the light-emitting unit comprises a plurality of first light-emitting units that emits light of a same color; and
a touch component, arranged on a side of the light-emitting unit away from the substrate, wherein
the touch component comprises a touch trace;
the touch trace comprises a first segment and a second segment; the first segment and the second segment are distributed along a periphery of a same first light-emitting unit of the plurality of first light-emitting units; the first segment and the second segment extend in different directions; and the first segment is provided with a first slit that extends through the first segment in a thickness direction of the first segment; and
a plurality of first segments on peripheries of the plurality of first light-emitting units extends in a same direction.

2. The display panel according to claim 1, wherein on a periphery of a same first light-emitting unit, more than two first segments are arranged extending in a same direction.

3. The display panel according to claim 2, wherein
the touch trace further comprises two first segments arranged oppositely to each other along a first direction and two second segments arranged oppositely to each other along a second direction;
the two first segments and the two second segments are alternately connected end-to-end around the first light-emitting unit; and
the first direction intersects with the second direction.

4. The display panel according to claim 1, wherein
the light-emitting unit further comprises a plurality of second light-emitting units that emits light of a same color and a plurality of third light-emitting units that emits light of a same color; and the first segment is distributed on a periphery of a second light-emitting unit of the plurality of second light-emitting units and/or a third light-emitting unit of the plurality of third light-emitting units; or
the touch trace comprises a third segment distributed on a periphery of a same second light-emitting unit and/or a same third light-emitting unit; an extension direction of the third segment is different from an extension direction of the first segment; and the third segment is provided with a second slit that extends through the third segment in a thickness direction of the third segment.

5. The display panel according to claim 1, wherein
a first light-emitting unit of the plurality of first light-emitting units is a red light-emitting unit; and the first segment on a periphery of a plurality of red light-emitting units are provided with the first slit; or
the light-emitting unit further comprises a red light-emitting unit emitting light in a different color than the first light-emitting unit; the touch trace comprises a ring segment located on a periphery of a red light-emitting unit of the plurality of red light-emitting units; and the ring segment is in a closed ring shape.

6. The display panel according to claim 1, wherein quantities of first slits on the periphery of the plurality of first light-emitting units are identical.

7. The display panel according to claim 1, wherein
the touch trace comprises a plurality of touch electrodes; at least two adjacent touch electrodes are spaced apart to form a separation slit; and at least one first slit is reused as the separation slit.

8. The display panel according to claim 7, wherein the plurality of touch electrodes comprises an effective electrode and a dummy electrode; and the dummy electrode comprises at least one first segment.

9. The display panel according to claim 8, wherein the effective electrode comprises a touch sensing electrode and/or a touch driving electrode.

10. The display panel according to claim 7, wherein at least one touch electrode comprises a through-hole that traverses the touch electrode; and a plurality of through-holes are spaced apart on the touch electrode.

11. The display panel according to claim 7, further comprising a first touch layer and a second touch layer, wherein
the plurality of touch electrodes is located on the first touch layer; the second touch layer is provided with a bridging part; and at least two adjacent touch electrodes are electrically connected to each other through the bridging part; and
a touch electrode of the plurality of touch electrodes comprises a touch area and a bridging area; an orthographic projection of the bridging area on the substrate overlaps with an orthographic projection of the bridging part on the substrate; an orthographic projection of the touch area on the substrate is located outside the orthographic projection of the bridging part on the substrate; and the first segment is located in the touch area.

12. The display panel according to claim 1, wherein at least a portion of a surface of the touch trace away from the light-emitting unit is provided with a protrusion structure.

13. The display panel according to claim 12, wherein the light-emitting unit comprises a red light-emitting unit; and at least a portion of a surface of the touch trace located on a periphery of the red light-emitting unit includes the protrusion structure.

14. The display panel according to claim 12, wherein the protrusion structure is provided on the first segment; and the protrusion structure is located on both sides of the first slit in an extension direction of the first segment.

15. The display panel according to claim 12, further comprising multiple protrusion structures, wherein the multiple protrusion structures are spaced apart along an extension direction of the touch trace.

16. The display panel according to claim 1, wherein
the touch trace encloses to form a hollow area; an orthographic projection of the light-emitting unit on the substrate is located in an orthographic projection of the hollow area on the substrate; and the first segment is a portion of the touch trace that encloses to form the hollow area.

17. The display panel according to claim 1, wherein
one first slit is provided on a same first segment; or
multiple first slits are provided on the first segment and are spaced apart in an extension direction of the first segment.

18. A display apparatus, comprising:
a display panel, comprising
a substrate;
a light-emitting unit, arranged on a side of the substrate, wherein the light-emitting unit comprises a plurality of first light-emitting units that emits light of a same color; and
a touch component, arranged on a side of the light-emitting unit away from the substrate, wherein
the touch component comprises a touch trace;
the touch trace comprises a first segment and a second segment; the first segment and the second segment are distributed along a periphery of a same first light-emitting unit of the plurality of first light-emitting units; the first segment and the second segment extend in different directions; and the first segment is provided with a first slit that extends through the first segment in a thickness direction of the first segment; and
a plurality of first segments on peripheries of the plurality of first light-emitting units extends in a same direction.
